(19) United States
(12) Patent Application Publication
(10) Pub. No.: US 2013/0285593 A1
(43) Pub. Date: Oct. 31, 2013

(54) CARD-STYLE SOLAR CHARGER AND METHOD FOR MANUFACTURING THE SAME

(71) Applicant: Rong-Shian Chu, Miaoli County (TW)

(72) Inventor: Rong-Shian Chu, Miaoli County (TW)

(21) Appl. No.: 13/649,464

(22) Filed: Oct. 11, 2012

(30) Foreign Application Priority Data
Apr. 27, 2012 (TW) 101207945

(51) Int. Cl. H02J 7/00; H05K 13/00

(52) U.S. Cl. 320/101; 156/60

(57) ABSTRACT

A card-style solar charger includes a flexible substrate, a solar cell, and a transparent cover membrane which are stacked up in bottom-to-top order and is characterized in that the card-style solar charger has an output end electrically connected to a connector of a transmission cable for supplying electric power. The card-style solar charger comes with different output ends to suit different contacts of a connector. Due to its card-like appearance and its way of generating solar power, the card-style solar charger is portable, lightweight, compact, easy to use, capable of instant charging, and widely applicable.

### CROSS-REFERENCE TO RELATED APPLICATION

This non-provisional application claims priority under 35 U.S.C. §119(a) on Patent Application No(s). 101207945 filed in Taiwan, R.O.C. on Apr. 27, 2012, the entire contents of which are hereby incorporated by reference.

### FIELD OF THE INVENTION

The present invention relates to card-style solar chargers, and more particularly, to a card-style solar charger comprising an output end disposed on a card-style substrate.

### BACKGROUND OF THE INVENTION

At present, due to the rapid development of the electronic industry, information industry, and communication industry, their products follow the trend toward being lightweight and compact in order for their products not to be portable and space-saving. However, portable electronic products operating outdoors are seldom capable of accessing an external power source but have to be powered by in-built battery (commonly known as secondary batteries.)

In attempt to solve the aforesaid problem, related prior art discloses providing at least two batteries such that there is always a spare battery for replacing timely an operating battery running out of power. Nonetheless, the aforesaid prior art copes with the aforesaid problem by bringing about a new problem—the weight of the spare battery burdens the user carrying the portable electronic product.

Another attempt to solve the aforesaid problem involves recharging an operating battery running out of power. A conventional recharging process always takes place at a stationary power-supplying device, such as an electrical outlet, for supplying the recharging power. This conventional recharging process was good until recently. Recent years sees the birth of robust portable electronic device using conventional rechargeable batteries being recharged more often than ever before. Given a portable electronic device equipped with one and only one conventional rechargeable battery, the time taken to recharge the conventional rechargeable battery plus the fact that conventional rechargeable batteries nowadays are recharged more often than ever before means that the recharging-related interruption of the operation of portable electronic devices is inevitably longer and more often than ever before.

The prior art further discloses eliminating the aforesaid recharging-related interruption by means of solar chargers, as solar chargers can recharge rechargeable batteries continuously and as needed while the rechargeable batteries are operating, provided that sunlight is available. However, conventional solar chargers are disadvantageously bulky and thus not portable.

The bulkiness weakness led to the advent of ultra-slim conventional solar chargers which remain unfit for thorough elimination of the drawbacks of the related prior art. Ultra-slim solar chargers are not equipped with a power output device and thus have to be connected to a transmission cable and an output connector for outputting power generated from the solar chargers to the charging connector of another electronic device. The aforesaid design of the power output device is so complicated that it not only accounts for the difficulty facing the solar chargers in terms of storage and portability, but also explains why the junction of the transmission cable and the connector or the junction of the transmission cable and the charger is susceptible to circuit severing and contact detachment for long use, thereby posing a safety threat to the charger in operation.

### SUMMARY OF THE INVENTION

It is an objective of the present invention to overcome the aforesaid drawbacks of the prior art, that is, the bulkiness and high weight of conventional solar chargers, simplify the otherwise intricate connection-related design of conventional power output end, enhance the ease of use of conventional solar chargers, and remove risk factors in conventional solar chargers.

Hence, the present invention provides a card-style solar charger, comprising: a flexible substrate; a solar cell disposed on the flexible substrate and having two electrodes; and a transparent cover membrane disposed on the solar cell, wherein the card-style solar charger is characterized in that: the card-style solar charger has an output end disposed at an end of the flexible substrate and comprising two output electrodes electrically connected to the electrodes of the solar cell. The output end is electrically connected to a connector of a transmission cable for enabling power transmission.

In an embodiment of the present invention, the card-style solar charger is of a thickness of 1.2 mm.

In an embodiment of the present invention, the card-style solar cell has a compound thin film made of copper indium gallium selenide (CIGS) and adapted to serve as a sunlight-absorbing material layer.

The aforesaid card-style solar charger further comprises a converter electrically connected to the output electrodes. The converter increases the output voltage at the output end to 5V.

The aforesaid card-style solar charger meets ISO/IEC FDIS 7810 ID-1 requirements and is of dimensions of 85.60 mm by 53.98 mm.

The present invention discloses, in another preferred embodiment thereof, the output electrodes are each of a rectangular shape, such that the output end comprising the output electrodes is electrically connected to a connector as needed.

In another preferred embodiment, two slit-like openings are disposed at the same end of the card-style solar charger as the output end is. The output end comprises the output electrodes and the openings, wherein the output electrodes and the openings comply with Universal Serial Bus connector (USB connector) specifications in shape.

In a preferred embodiment, for example, the output end matches an A-type connector for use with a standard USB, whereas the output end matches a Micro-B connector for use with a Micro-USB.

The present invention further discloses a method for manufacturing the aforesaid card-style solar charger. The method comprises the steps of:

S1: providing a flexible substrate having an output end having two output electrodes mounted thereon;

S2: providing on the flexible substrate a solar cell having two electrodes electrically connected to the output electrodes, respectively;

S3: covering a plastic substrate fully with a transparent cover membrane outside the output electrodes; and

S4: laminating the transparent cover membrane and the flexible substrate to each other by thermal lamination.

In a preferred embodiment of the present invention, the output electrodes are of a rectangular shape each such that the output end comprising the output electrodes is electrically connected to a connector as needed.

In another preferred embodiment of the present invention, two slit-like openings are disposed at the same end of the flexible substrate as the output electrodes are, the output end comprising the output electrodes and the openings, wherein the output electrodes and the openings comply with Universal Serial Bus connector (USB connector) specifications in shape. In an aspect of the preferred embodiment, the output end matches an A-type connector for use with a standard USB. In another aspect of the preferred embodiment, the output end matches a Micro-B connector for use with a Micro-USB.

Optionally, the aforesaid method further comprises the step of disposing on the card-style solar charger a converter electrically connected to the output electrodes, wherein the converter increases the output voltage at the output end to 5V.

In conclusion, a card-style solar charger provided by the present invention comes with different output ends to suit different contacts of a connector, and thus users can choose the card-style solar charger equipped with an output end that matches a unique contact of a connector, thereby dispensing with the hassles of connecting the solar charger to an external transmission cable. Due to its card-like appearance and its way of generating solar power, the card-style solar charger is portable, lightweight, compact, easy to use, capable of instant charging, and widely applicable.

In a situation where sunlight is available steadily, the card-style solar charger of the present invention recharges the rechargeable battery of a portable electronic device in real time as needed while the portable electronic device is operating; hence, the operation of the portable electronic device is unlikely to be interrupted, because the rechargeable battery would not run out of power.

### BRIEF DESCRIPTION OF THE DRAWINGS

Objectives, features, and advantages of the present invention are hereunder illustrated with specific embodiments in conjunction with the accompanying drawings, in which:

FIG. 1 is a schematic view of a card-style solar charger according to the present invention;

FIG. 2 is a schematic view of a layered stacking architecture of the card-style solar charger of FIG. 1;

FIG. 3 is a schematic view as to how to operate the card-style solar charger according to a preferred embodiment of the present invention;

FIG. 4 is a schematic view as to how to operate the card-style solar charger according to another preferred embodiment of the present invention; and

FIG. 5 is a schematic view of the card-style solar charger equipped with a converter according to yet another preferred embodiment of the present invention.

### DETAILED DESCRIPTION OF THE PREFERRED EMBODIMENTS

### Card-Style Solar Charger

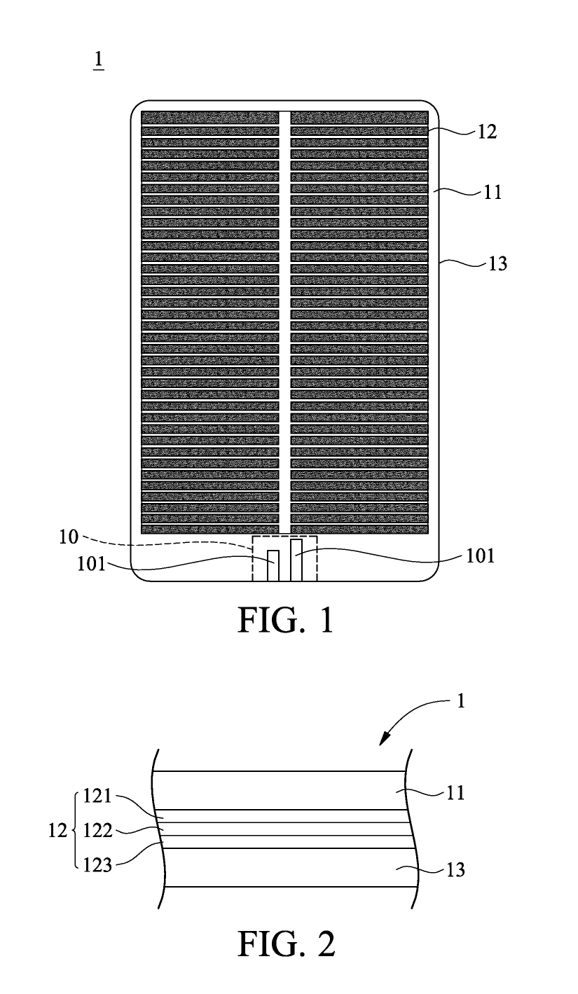

Referring to FIG. 1 and FIG. 2, the present invention provides a card-style solar charger 1 comprising a flexible substrate 13, a solar cell 12, and a transparent cover membrane 11 which are stacked up, with the flexible substrate 13 being at the bottom, the solar cell 12 being in the middle, and the transparent cover membrane 11 being at the top. An output end 10 (whose periphery is indicated by a dashed line for serving an illustrative purpose instead of a restrictive purpose) is disposed at one end of the flexible substrate 13. The output end 10 comprises two output electrodes 101. The card-style solar charger 1 is, as its name suggests, card-shaped, resembles a debit card or a credit card which is in wide use, meets ISO/IEC FDIS 7810 ID-1 series requirements, and is of dimensions of 85.60 mm by 53.98 mm. The card-style solar charger 1 of the present invention is lightweight and portable and thus has high applicability.

The flexible substrate 13 is, as its name suggests, made of a flexible and resilient material, such as PET or any other appropriate plastics. The two output electrodes 101 are mounted on one side at the end of the flexible substrate 13.

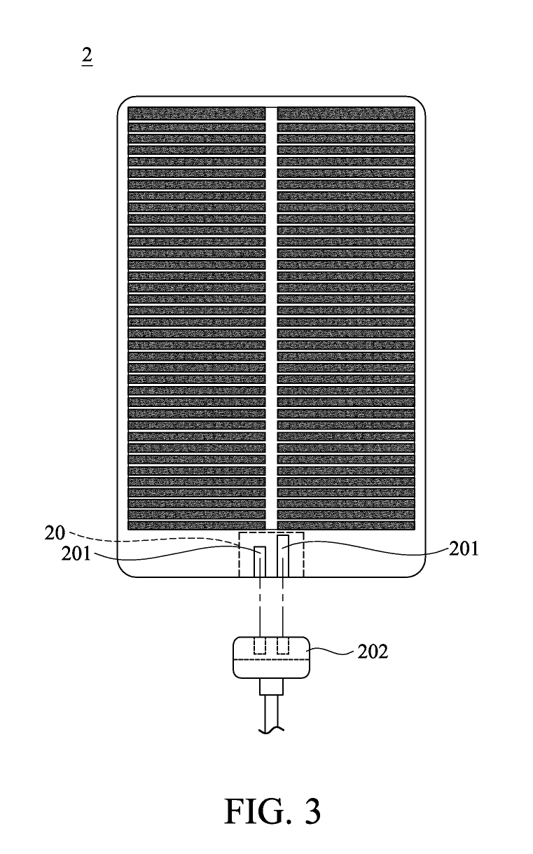

Referring to FIG. 3, in a preferred embodiment, an output end 20 (whose periphery is indicated by a dashed line for serving an illustrative purpose instead of a restrictive purpose) disposed at one end of a card-style solar charger 2 comprises two output electrodes 201. Each of the output electrodes 201 can be of a slender shape or a rectangular shape, provided that each of the output electrodes 201 corresponds in shape to a custom-made dedicated connector 202 or a charging-oriented connector of a conventional electronic device, such that connectors can be electrically connected to the output electrodes 201 as soon as the connectors are inserted into the card-style solar charger 2.

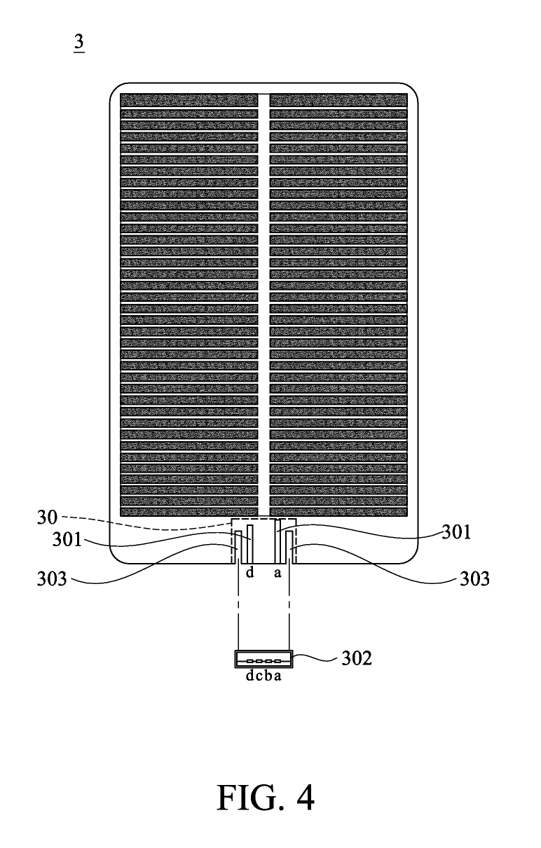

Referring to FIG. 4, in another preferred embodiment, an output end 30 (whose periphery is indicated by a dashed line for serving an illustrative purpose instead of a restrictive purpose) disposed at one end of a card-style solar charger 3 comprises two output electrodes 301. Each of the output electrodes 301 can be of a slender shape or a rectangular shape. Two slit-like openings 303 are disposed at the same end of the card-style solar charger 3 as the output end 30 is. Shape-related features, such as the depth of the output electrodes 301 and the two openings 303 and the distance between the two openings 303 comply with the specifications of Universal Serial Bus connectors (USB connectors). Hence, once a USB connector 302 (such as an A-type connector for use with a standard USB) is inserted into and electrically connected to the output end 30, the openings 303 will fix the USB connector 302 in place, and in consequence contacts of the USB connector 302 will be accurately electrically connected to the output electrodes 301 for transmitting power. For example, contacts a, b, c, d serve contact-related functions V_{Bus}, D−, D+, and grounding, respectively. Furthermore, it is feasible that a USB connector of a configuration not described above has an ID contact (not shown), optionally.

Referring to FIG. 1 and FIG. 2, the solar cell 12 is a compound thin-film solar cell or any other non-thin-film solar cell which has a layered stacking architecture, such as a silicon solar cell. In this regard, the present invention provides, in a preferred embodiment thereof, the solar cell 12 for use in providing electric power through photoelectrical conversion. For example, the layered stacking architecture of the solar cell 12 is a monolayer or a bilayer. Specifically speaking, the solar cell 12 comprises a substrate 123, a compound thin film 122, and a finger electrode 121. The substrate 123 functions as the positive pole and is made of stainless steel. The compound thin film 122 is disposed between the substrate 123 and the finger electrode 121 and is made of a sunlight-absorbing material, such as copper indium gallium selenide (CIGS); however, the present invention is not limited thereto, as it is also feasible for the compound thin film 122 of the present invention to be replaced with any other compound thin film applicable to the aforesaid cell structure for use in solar power generation. For example, the compound thin film 122 consists of five layers as follows: (1) a lower electrode made of chromium (Cr), molybdenum-sodium (MoNa), and molybdenum (Mo), (2) a sunlight-absorbing material layer made of copper indium gallium selenide (CIGS), (3) a buffer layer made of cadmium sulfide (CdS) or zinc sulfide (ZnS), (4) a window layer made of zinc oxide (ZnO), and (5) a transparent conductive layer (made of aluminum-doped zinc oxide, AZO). The finger electrode 121 functions as a negative pole and is made of silver to thereby form a silver finger electrode. The substrate 123 and the finger electrode 121 are electrically connected to the output electrodes 101 of the flexible substrate, respectively.

The transparent cover membrane 11 is made of a transparent material and adapted to protect the solar cell 12 by covering the flexible substrate 13 fully. However, the transparent cover membrane 11 does not cover a contact-disposed region of the output electrodes 101, and thus the contact-disposed region is exposed such that it can come into electrical contact with another device as needed.

Accordingly, each of the aforesaid card-style solar chargers in a preferred embodiment of the present invention has an output end. The output end comprises the aforesaid output electrodes which are each electrically connected to the electrodes of the solar cell, such that the output ends of the card-style solar chargers are directly electrically connected to different connectors according to the dimensions and shapes of the output electrodes. For example, in several preferred embodiments, the output end is electrically connected to a custom-made dedicated connector, an A-type connector for use with a standard USB, and a Micro-B connector for use with a Micro-USB.

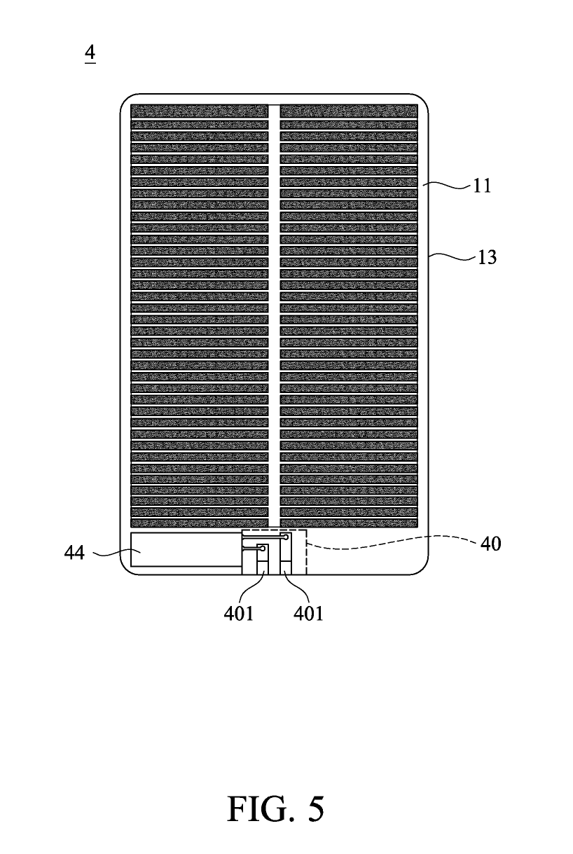

Referring to FIG. 5, in another preferred embodiment, a card-style solar charger 4 of the present invention comprises a converter 44. The converter 44 is electrically connected to output electrodes 401 of an output end 40 (whose periphery is indicated by a dashed line for serving an illustrative purpose instead of a restrictive purpose). The converter 44 increases the output voltage at the output end to 5V so as to render charging faster and more efficient.

In conclusion, the card-style solar charger not only carries out charging instantly and quickly by means of solar power generation, but is also easy to carry and store because it is compact and lightweight.

### [Method for Manufacturing Card-Style Solar Charger]

A method for manufacturing a card-style solar charger disclosed in the aforesaid preferred embodiments is described in detail below to further prove that the present invention can be readily implemented.

First, a plastic substrate is provided to serve as a flexible substrate. The aforesaid output electrodes 401 are mounted on the flexible plastic substrate and disposed at recesses formed thereon, wherein the recesses are of appropriate size. In a preferred embodiment, two openings corresponding in position to a USB connector are formed on the plastic substrate.

Second, a CIGS solar cell of a bilayer structure is produced in the following steps:
I. provide a stainless steel substrate of a thickness less than 200 μm to serve as the positive pole;
II. form consecutively on the stainless steel substrate the following: chromium (Cr) layer, molybdenum-sodium (MoNa) layer, and molybdenum (Mo) layer;
III. put the aforesaid components in a vacuum chamber at high temperature, introduce selenium gas into the vacuum chamber continuously, and deposit on the molybdenum (Mo) layer by sputter-deposition in the following three stages:
   (1) indium (In) and copper gallium (CuGa);
   (2) copper gallium (CuGa), copper (Cu) and indium (In); and
   (3) indium (In) and copper-gallium (CuGa);
      upon completion of the sputter-deposition process, a sunlight-absorbing material layer is formed;
IV. on the sunlight-absorbing material layer, a buffer layer composed of cadmium sulfide (CdS) or zinc sulfide (ZnS) is formed;
V. on the buffer layer, a window layer composed of zinc oxide (ZnO) is formed; and
VI. form a transparent conductive layer (AZO) on the window layer.

Finally, a silver finger electrode which functions as a negative pole is 10 μm thick and is formed on the transparent conductive layer, so as to finalize the production process of the CIGS solar cell.

The electroplated layer between the stainless steel substrate and the silver finger electrode is 5 μm or less in thickness. The thickness of the battery in its entirety is 220 μm or less in thickness.

Afterward, the CIGS solar cell thus produced is put in the recesses and on the plastic substrate mounted thereon with the output electrodes 401. The silver finger electrode and the stainless steel substrate of the CIGS solar cell are connected to the output electrodes 401 on the plastic substrate by wire bonding or soldering.

At last, outside the output electrodes 401, the plastic substrate is fully covered with a transparent plastic membrane or a transparent plastic cover which functions as the transparent cover membrane, and then the transparent plastic membrane or the transparent plastic cover and the plastic substrate are laminated to each other by thermal lamination, so as to form the card-style solar charger of the present invention. The card-style solar charger of the present invention is of a thickness of 1.2 mm, but the present invention is not limited thereto. Persons skilled in the art understand that the thickness of the card-style solar charger of the present invention can be configured to range between 0.8 mm and 2 mm as needed.

Optionally, a converter is disposed on the aforesaid card-style solar charger. The converter is electrically connected to the output electrodes 401 and increases the output voltage at the output end of the card-style solar charger to 5V.

The present invention is disclosed above by preferred embodiments. However, persons skilled in the art should understand that the preferred embodiments are illustrative of the present invention only, but should not be interpreted as restrictive of the scope of the present invention. Hence, all equivalent modifications and replacements made to the aforesaid embodiments should fall within the scope of the present invention. Accordingly, the legal protection for the present invention should be defined by the appended claims.

What is claimed is:

1. A card-style solar charger, comprising:
a flexible substrate;
a solar cell disposed on the flexible substrate and having two electrodes; and
a transparent cover membrane disposed on the solar cell,
wherein the card-style solar charger is characterized in that: the card-style solar charger has an output end disposed at an end of the flexible substrate and comprising two output electrodes electrically connected to the electrodes of the solar cell.

2. The card-style solar charger of claim 1, wherein the card-style solar charger is of a thickness of 1.2 mm.

3. The card-style solar charger of claim 2, further comprising a converter electrically connected to the output electrodes.

4. The card-style solar charger of claim 1, wherein the card-style solar charger meets ISO/IEC FDIS 7810 ID-1 requirements and is of dimensions of 85.60 mm by 53.98 mm.

5. The card-style solar charger of claim 1, wherein the output electrodes are of a rectangular shape each such that the output end comprising the output electrodes is electrically connected to a connector as needed.

6. The card-style solar charger of claim 1, wherein two slit-like openings are disposed at a same end of the card-style solar charger as the output end is, the output end comprising the output electrodes and the openings, wherein the output electrodes and the openings comply with Universal Serial Bus connector (USB connector) specifications in shape.

7. The card-style solar charger of claim 6, wherein the output end matches an A-type connector for use with a standard USB.

8. The card-style solar charger of claim 6, wherein the output end matches a Micro-B connector for use with a Micro-USB.

9. A method for manufacturing a card-style solar charger, comprising the steps of:
S1: providing a flexible substrate having an output end having two output electrodes mounted thereon;
S2: providing on the flexible substrate a solar cell having two electrodes electrically connected to the output electrodes, respectively;
S3: covering a plastic substrate fully with a transparent cover membrane outside the output electrodes; and
S4: laminating the transparent cover membrane and the flexible substrate to each other by thermal lamination.

10. The method of claim 9, wherein the card-style solar charger is of a thickness of 1.2 mm.

11. The method of claim 10, further comprising the step of:
S5: providing on the card-style solar charger a converter electrically connected to the output electrodes.

12. The method of claim 9, wherein the card-style solar charger meets ISO/IEC FDIS 7810 ID-1 requirements and is of dimensions of 85.60 mm by 53.98 mm.

13. The method of claim 9, wherein the output electrodes are of a rectangular shape each such that the output end comprising the output electrodes is electrically connected to a connector as needed.

14. The method of claim 9, wherein, in step S1, two slit-like openings are disposed at a same end of the flexible substrate as the output electrodes are, the output end comprising the output electrodes and the openings, wherein the output electrodes and the openings comply with Universal Serial Bus connector (USB connector) specifications in shape.

15. The method of claim 14, wherein the output end matches an A-type connector for use with a standard USB.

16. The method of claim 14, wherein the output end matches a Micro-B connector for use with a Micro-USB.
